(19) United States
(12) Patent Application Publication
(10) Pub. No.: US 2026/0362991 A1
(43) Pub. Date: Nov. 12, 2026

(54) HYPERBOLIC METAMATERIAL NEAR-FIELD EMITTER STRUCTURED BY CHI-RECOGNITION GEOMETRY

(71) Applicant: Jonathan Washburn, Austin, TX (US)

(72) Inventor: Jonathan Washburn, Austin, TX (US)

(21) Appl. No.: 19/672,363

(22) Filed: May 8, 2026

Related U.S. Application Data
(60) Provisional application No. 63/804,597, filed on May 12, 2025.

(51) Int. Cl. H10N 97/00; F28D 21/00; H10F 77/12; H10F 77/169

(52) U.S. Cl. CPC H10N 97/00; F28D 21/00; H10F 77/12; H10F 77/169

(57) ABSTRACT

A near-field thermal emitter includes a multilayer hyperbolic metamaterial stack having alternating conductive and dielectric layers arranged at a conductive-to-dielectric thickness ratio of 1/phi, thereby yielding a conductive fill fraction of phi\hat{ }−2, and a chi-lattice surface pattern at an emitting side of the stack. The stack satisfies an opposite-sign condition between epsilon_parallel and epsilon_perp over a selected operating band at f=phi\hat{ }−2, and the surface pattern includes counter-helical paths arranged to satisfy a directionality metric. In use, the emitter may be positioned across a subwavelength gap from a receiver or thermally coupled body so that evanescent modes transfer thermal energy at a rate exceeding a far-field blackbody transfer rate computed for the same temperatures and projected area.

### CROSS-REFERENCE TO RELATED APPLICATIONS

This application claims the benefit of U.S. Provisional Patent Application No. 63/804,597, filed May 12, 2025, the entire disclosure of which is incorporated herein by reference.

### BACKGROUND OF THE INVENTION

The present disclosure relates generally to thermal radiation engineering, near-field radiative heat transfer, and hyperbolic metamaterial emitter structures, and more particularly to hyperbolic metamaterial emitter and emitter-receiver architectures whose anisotropic permittivity and in-plane surface geometry are structured using phi-derived layer scaling and chi-patterned recognition geometry to achieve enhanced and directionally controlled near-field thermal emission.

In the far field, thermal radiation is bounded by Planck-law blackbody behavior for a surface at a given temperature. When two structures are separated by distances larger than the relevant thermal wavelength, radiative transfer is generally limited to propagating modes and corresponding blackbody constraints. In the near field, however, when the spacing between an emitter and a receiving body is reduced below the relevant wavelength, evanescent electromagnetic modes can couple across the gap and transfer thermal energy at rates exceeding the far-field blackbody limit. This super-Planckian near-field transfer regime has created substantial interest in emitter structures capable of increasing photonic density of states, supporting large-k modes, and directing thermal radiation into useful coupled channels.

Known near-field radiative transfer systems have demonstrated enhancement using narrowband surface phonon polariton materials and closely spaced emitter-receiver surfaces. Such systems, including silicon carbide based configurations, can provide substantial transfer enhancement within limited spectral regions, but they are generally constrained by narrowband material behavior and do not provide the same combination of broadband hyperbolic enhancement and directed emission control addressed by the present disclosure.

Hyperbolic metamaterials have also been investigated as thermal emitters because anisotropic media having opposite-sign tensor components can support hyperbolic dispersion and a greatly increased photonic density of states. Bulk hyperbolic materials and multilayer metal-dielectric stacks have been used to produce broadband enhancement relative to conventional structures. However, prior multilayer hyperbolic metamaterial designs have generally relied on arbitrarily selected or numerically tuned layer thicknesses chosen for particular wavelengths or optimization targets, rather than on a structurally motivated fill-fraction rule that defines the stack architecture itself.

Patterned emitter surfaces have likewise been used to alter angular emission behavior, including through gratings, holes, metasurface features, and other in-plane structures. While such patterning can improve directionality or coupling in selected systems, prior in-plane pattern geometries are typically selected through numerical optimization or application-specific trial design and are not linked to the out-of-plane multilayer architecture by a unified first-principles structural rule. As a result, prior patterned hyperbolic structures have not provided the particular combined architecture in which the multilayer stack relation and the in-plane directional patterning are both structurally constrained parts of the emitter design.

Near-field thermophotovoltaic systems have also been proposed in which a thermal emitter is positioned across a nanoscale gap from a photovoltaic receiver so that evanescent coupling increases incident flux beyond far-field limits. These systems often rely on narrowband emitters, elevated emitter temperatures, or both. Although such systems illustrate the value of gap-controlled thermal coupling, they do not disclose the combined emitter architecture described here, and they do not provide the same disciplined framework for preserving near-ambient and low-delta-T embodiments as subordinate but supported use cases within a broader emitter-centered disclosure.

Accordingly, limitations remain in the prior art. Existing hyperbolic metamaterial designs generally do not employ a structurally motivated fill fraction in place of arbitrary or empirically tuned layer relations. Existing patterned emitter structures generally do not provide first-principles in-plane directional patterning tied to the multilayer architecture. Existing systems generally do not disclose a unified emitter architecture that combines broadband hyperbolic enhancement with directional and coherence-preserving surface patterning. Existing near-field emitter systems also do not provide the same disciplined support for near-ambient embodiments in a structured hyperbolic metamaterial emitter context.

For these and other reasons, a need remains for an emitter architecture in which a hyperbolic metamaterial stack and an in-plane directional pattern are jointly structured so that broadband hyperbolic enhancement, directional emission behavior, and near-field coupling can be achieved within a single coherent device framework. The present disclosure addresses that need.

### SUMMARY OF THE INVENTION

The present disclosure provides a thermally emissive structure for super-Planckian near-field radiative transfer comprising a hyperbolic metamaterial emitter whose out-of-plane multilayer architecture and in-plane surface geometry are jointly constrained by a phi-derived layer relation and a chi-recognition pattern, such that the structure provides broadband hyperbolic enhancement together with directional, coherence-preserving near-field emission across a subwavelength gap. The core invention is a near-field thermal emitter architecture, not a generic Recognition Science platform. The identity of the case remains centered on the emitter architecture itself.

In more particular implementations, the disclosure provides a near-field thermal emitter comprising an alternating conductive/dielectric hyperbolic metamaterial stack having a conductive-to-dielectric thickness ratio of 1/phi and resulting fill fraction phi\hat{ }−2, together with chi-lattice surface patterning including counter-helical paths at angular offset phi/pi, the stack exhibiting Type I or Type II hyperbolic dispersion and the patterned surface imparting directional emission and first-order decoherence cancellation for super-Planckian radiative transfer across a subwavelength gap. The invention structures the HMM in two ways. The invention sets the conductive-to-dielectric thickness ratio to 1/phi, yielding fill fraction f=phi\hat{ }−2. That phi-derived relation is structurally motivated and not empirically tuned in the core embodiment.

In operation, hyperbolic dispersion in the multilayer emitter increases photonic density of states and supports Purcell enhancement relative to conventional emissive structures. The phi-scaled stack fixes a structurally motivated fill fraction for the emitter architecture. The chi-lattice surface pattern imparts directional emission behavior and preserves first-order decoherence cancellation in preferred patterned embodiments. When the emitter is positioned across a subwavelength gap from a receiver or other thermally coupled body, evanescent electromagnetic modes couple across the gap to produce enhanced near-field thermal transfer. The disclosed emitter architecture may be incorporated into electrical-conversion systems, cooling systems, switching systems, sensing systems, and other downstream implementations, but such downstream systems do not redefine the core invention.

In preferred implementations, the emitter is configured for operation in a mid-infrared band, including implementations in the 8-14 um atmospheric window. Preferred material systems include doped Si/SiO2 and SiC/SiO2 combinations for semiconductor-compatible and relatively low-loss mid-infrared embodiments, although other conductive and dielectric material families may be used. Preferred geometric implementations include lattice constants selected in relation to the intended operating wavelength, patterned surface features formed in a top dielectric layer, and spacer-controlled gap structures, including MEMS-based spacer structures, that maintain subwavelength separation between the emitter and a receiver. Preferred receiver pairings include photovoltaic and rectifying receivers.

In optional or alternative implementations, the hyperbolic emitter may be configured to operate in either a Type I or Type II regime depending on material selection, operating band, and effective-medium sign structure. Alternative conductive layers may include conductive oxides or noble metals, and alternative dielectric layers may include oxide, fluoride, or semiconductor dielectrics selected according to loss posture, fabrication compatibility, and target-band performance. Optional downstream implementations include HgCdTe receiver systems, chi-grid rectenna receiver systems, radiative-cooling systems, thermal-switch systems, thermal-sensor systems, wearable systems, waste-heat systems, building thermal-management systems, data-center systems, and spacecraft thermal-management systems. These remain subordinate to the core emitter architecture.

The present disclosure is further supported by formalized derivations and machine-verified model relations, including fill_fraction_eq, purcell_enhanced establishing that Purcell enhancement exceeds unity when Lambda is less than lambda/2, near_field_super_planckian establishing that near-field enhancement exceeds unity when d is less than lambda divided by 2pi, total_exceeds_components, chi_volume_ratio, coherence_exponent_eq_5, and sum_8_phases_eq_zero. These formalized relations support internal coherence, exact derived relations, and claim-support architecture, but do not by themselves constitute hardware prototype validation.

The disclosure also preserves secondary architecture anchors that are not required to define the broadest independent claim, but that remain expressly disclosed as subordinate support and dependent-claim territory. These secondary architecture anchors include extraction locked to integer multiples of E_coh=phi\hat{ }−5, synchronization to the eight-tick cadence, recognition-angle alignment at theta0=arccos(¼), and master-certificate support linking coherence exponent equal to 5 and eight-tick phase cancellation. These secondary anchors may be used in narrower claim families or continuation practice without altering the central identity of the invention as a chi-patterned, phi-scaled hyperbolic metamaterial near-field emitter architecture.

### BRIEF DESCRIPTION OF THE DRAWINGS

FIG. 1 depicts a high-level perspective or sectional schematic of a core emitter architecture including a hyperbolic metamaterial emitter stack, a chi-patterned surface, a subwavelength gap, and a representative receiver.

FIG. 2 depicts representative Type I and Type II hyperbolic isofrequency surfaces and associated anisotropic effective-medium tensor relationships supporting hyperbolic metamaterial behavior.

FIG. 3 depicts a sectional view of a phi-scaled layer stack including alternating metal and dielectric layers, the fixed relation d_m/d_d=1/phi, the resulting fill fraction phi\hat{ }−2, and representative dimensional relationships.

FIG. 4 depicts a top plan view of a chi-lattice surface pattern including counter-helical paths, an angular offset phi/pi, volumetric phase ratio phi, recognition-angle alignment, and representative pattern periodicity.

FIG. 5 depicts directional-emission and decoherence-cancellation behavior associated with the patterned emitter surface, including a preferred primary lobe, representative side-lobe suppression, and paired paths associated with first-order decoherence cancellation.

FIG. 6 depicts a cross-sectional emitter-receiver system showing near-field evanescent coupling across a maintained nanoscale gap.

FIG. 7 depicts a representative fabrication and assembly flow including stack deposition, surface patterning, spacer formation, and emitter-to-receiver integration.

FIG. 8 depicts a preferred electrical-conversion embodiment including an emitter, a gap, a photovoltaic or rectifying receiver, electrical contacts, and a representative thermal-to-electrical conversion path.

FIG. 9 depicts a secondary radiative-cooling embodiment including directional emission toward the sky and suppression of undesired lateral or downward thermal exchange.

FIG. 10 depicts a secondary variable-gap thermal-switch embodiment including an ON gap, an OFF gap, and an actuator.

FIG. 11 depicts a secondary design and validation workflow including design inputs, effective-medium calculation, Purcell calculation, near-field calculation, directional-pattern selection, fabrication checks, and optional formal verification.

FIG. 12 depicts a secondary enhanced thermal-sensor embodiment including emitter-assisted concentration of thermal radiation into a detector region.

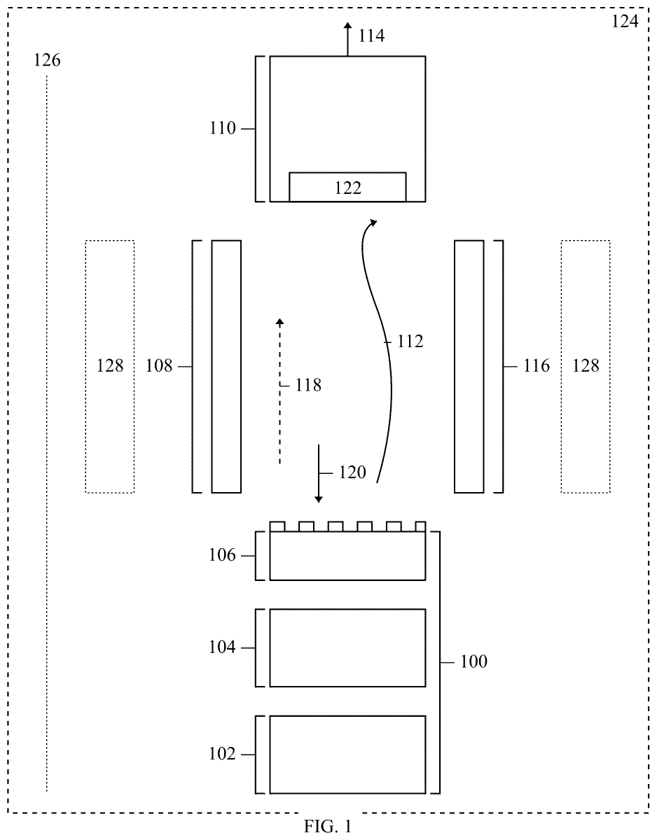

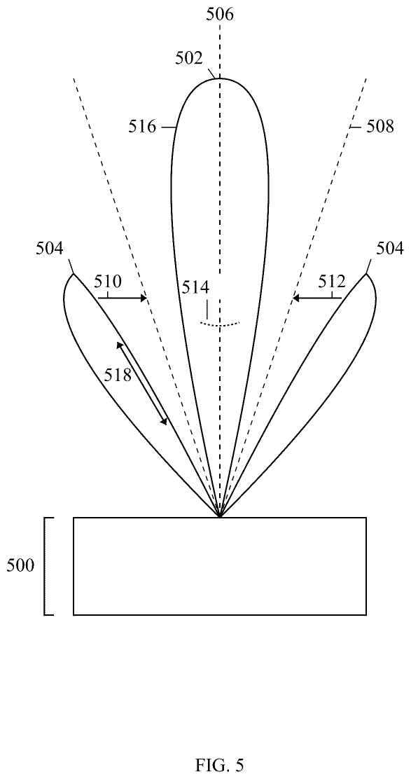

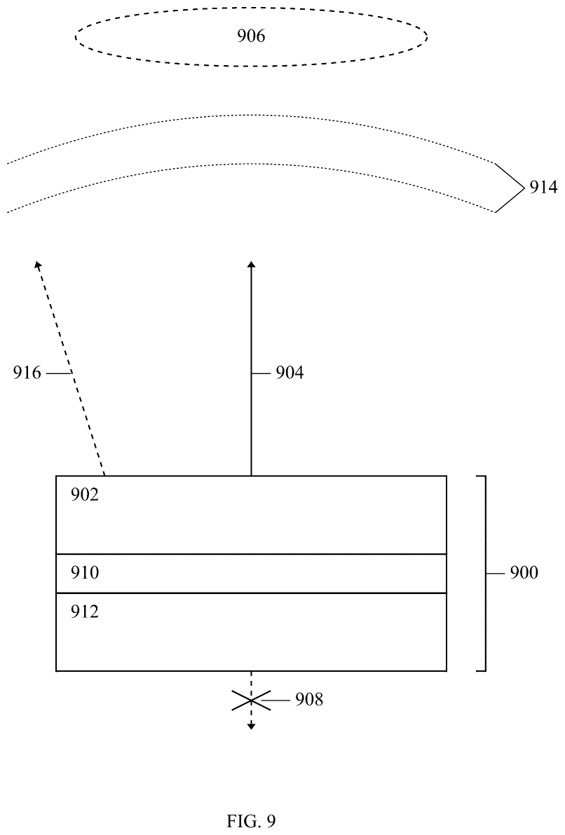

FIGS. 1-4 establish the core invention architecture, FIGS. 5-8 provide core-support and preferred-system detail, and FIGS. 9-12 provide subordinate downstream embodiments and support workflows.

### DETAILED DESCRIPTION OF THE INVENTION

Referring initially to FIG. 1, a near-field thermal transfer architecture may include an emitter structure 100 supported on a substrate 102. The emitter structure 100 may include a multilayer hyperbolic metamaterial stack 104 and a top patterned surface 106 disposed at an emitting side of the multilayer hyperbolic metamaterial stack 104. The emitter structure 100 may be positioned across a subwavelength gap 108 from a receiver 110 or another thermally coupled body. A thermal flux path 112 may extend from the emitter structure 100 toward the receiver 110 across the subwavelength gap 108, and in selected embodiments an optional electrical output path 114 may extend from or be associated with the receiver 110. One or more spacer structures 116 may maintain the subwavelength gap 108 in a selected range, and a surface normal 118 may extend outward from the top patterned surface 106 to provide a directional reference axis. In moderate-detail implementations, FIG. 1 may further include a patterned emission region 120 defined on the top patterned surface 106, a receiver active region 122 positioned opposite the patterned emission region 120, a support or package boundary 124 surrounding an active transfer zone, a lateral alignment reference 126 between the emitter structure 100 and the receiver 110, and an optional thermal isolation region 128 positioned laterally outside the primary transfer path. The illustrated arrangement is representative and may be implemented in a variety of geometric, material, and packaging forms so long as the core architecture remains centered on a phi-scaled hyperbolic metamaterial emitter having chi-patterned in-plane geometry for near-field thermal transfer.

The present disclosure provides a near-field thermal emitter architecture in which the hyperbolic metamaterial emitter is structured in two ways that together define the operative and load-bearing architecture of the invention. In a first structural aspect, the emitter structure 100 is formed as an out-of-plane multilayer hyperbolic metamaterial stack 104 including alternating conductive and dielectric layers arranged according to a phi-derived layer relation. In a second structural aspect, the top patterned surface 106 is provided with an in-plane chi-lattice pattern that imparts directional emission behavior and preserves first-order decoherence cancellation in preferred patterned embodiments. The invention is therefore not merely an arbitrary hyperbolic emitter with optional surface texturing. Rather, the invention structures the HMM in two ways, namely by the phi-scaled multilayer hyperbolic metamaterial stack 104 and by the chi-patterned top patterned surface 106, and those two structural aspects cooperate in the disclosed near-field emitter architecture.

The identity of the disclosed subject matter remains centered on a chi-patterned, phi-scaled hyperbolic metamaterial emitter configured for use across a subwavelength gap 108. The technical improvement is implemented in emitter hardware structure and near-field coupling physics, including the multilayer stack geometry, the patterned emitting surface, and the maintained subwavelength coupling gap, rather than in abstract mathematics, generic optimization, or recognition theory standing alone. Downstream receiver branches, electrical-conversion branches, cooling branches, switching branches, sensing branches, and application-specific product families are preserved in the disclosure, but they do not redefine the technical center of the invention.

In representative implementations, the emitter structure 100 includes the multilayer hyperbolic metamaterial stack 104 formed over the substrate 102 and including alternating conductive and dielectric layers extending generally parallel to the top patterned surface 106. The conductive layers may be metallic, plasmonic, phonon-polaritonic, doped-semiconductor, conductive-oxide, or otherwise conductive layers selected to produce a desired effective-medium response in a selected operating band. The dielectric layers may be oxide, fluoride, semiconductor, or other dielectric layers selected in relation to dielectric loss, fabrication compatibility, and intended band performance. The multilayer hyperbolic metamaterial stack 104 therefore defines an anisotropic effective-medium structure having different effective responses for fields parallel and perpendicular to the layer plane. In this way, the stack 104 provides the out-of-plane hyperbolic architecture, while the top patterned surface 106 provides the in-plane directional architecture.

The near-field operating environment shown in FIG. 1 is not incidental. The emitter structure 100 is configured for use across the subwavelength gap 108 from the receiver 110 or another thermally coupled body so that evanescent electromagnetic modes can couple across the subwavelength gap 108. In this regime, transfer need not be limited to far-field propagating modes or blackbody constraints. Instead, the thermal flux path 112 may include near-field coupled transfer contributions that exceed a far-field blackbody transfer limit. Accordingly, the combination of the structured emitter architecture and the subwavelength gap 108 supports super-Planckian near-field radiative transfer. The optional electrical output path 114 is shown because certain preferred and downstream embodiments convert transferred thermal radiation into electrical output, but the optional electrical output path 114 is not required to define the broadest emitter architecture.

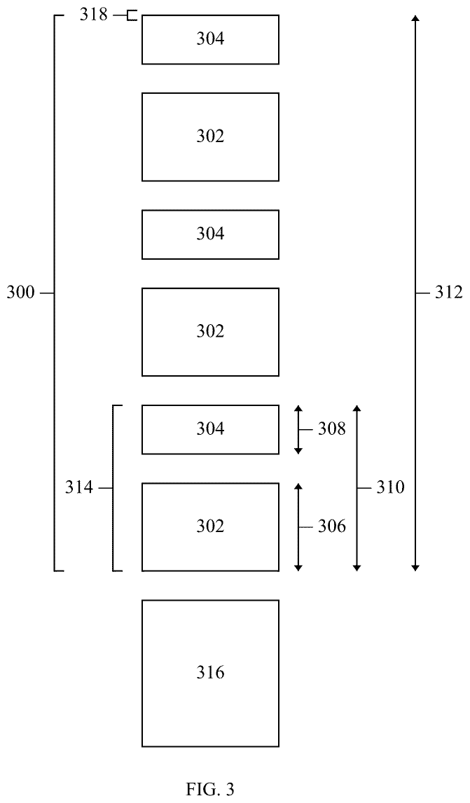

Referring now to FIG. 3, a representative layer stack 300 is shown over a substrate 316 and includes alternating dielectric layers 302 and metal layers 304 terminating at a top interface 318. A dielectric thickness 306 corresponds to d_d, a metal thickness 308 corresponds to d_m, a period 310 corresponds to Lambda, a stack thickness 312 corresponds to the overall multilayer thickness, and a fill fraction 314 corresponds to the conductive fill fraction f. In the core embodiment, the out-of-plane multilayer architecture is governed by two load-bearing structural rules. First, the invention sets the conductive-to-dielectric thickness ratio to 1/phi. Second, that imposed layer relation yields a fill fraction f=phi\hat{ }−2. More specifically, where the metal thickness 308 is d_m and the dielectric thickness 306 is d_d, the core stack relation is d_m/d_d=1/phi, where phi=(1+sqrt(5))/2. The resulting fill fraction 314 is f=d_m/(d_m+d_d)=1/(1+phi)=phi\hat{ }−2. In the core embodiment, this relation is structurally motivated and not empirically tuned. The phi-derived layer rule is used as a determinative structural rule of the disclosed emitter architecture rather than as a merely optional numerical optimization variable. The phi-derived stack rule is preserved because it performs architectural work in the invention. In disclosed implementations, phi\hat{ }−2 provides a structurally motivated fill-fraction rule for maintaining a broad hyperbolic operating posture rather than relying on arbitrary or purely empirical thickness selection, phi-ratio layering provides a self-similar tolerance rule under phi-related variation, and phi\hat{ }−2 provides a disclosed balance between conductive-layer loss contribution and dielectric-mode volume contribution. The cost relation J(f)=½(f+1/f)−1 may be preserved as support for the structural motivation of the selected fill fraction 314.

The disclosure also preserves concrete dimensional guidance so that the stack rule is not purely abstract. In one representative mid-infrared implementation, the dielectric thickness 306 may be about 60 nm and the metal thickness 308 may be about 37 nm, thereby yielding a period 310 of about 97 nm consistent with the phi-derived ratio. Representative layer stacks 300 may include from about 20 to about 50 periods, thereby producing stack thicknesses 312 of about 1.9 um to about 4.9 um. These values are preferred example dimensions and are not the only dimensions contemplated by the disclosure. The important point is that the layer stack 300 preserves the imposed relation between the dielectric thickness 306 and the metal thickness 308 so that the fill fraction 314 remains phi\hat{ }−2 while the selected material pair and target band support useful hyperbolic operation.

Different material families may be used to realize the disclosed stack 104 in different operating bands and implementation postures. Doped silicon and silicon carbide families are preferred where mid-infrared operation and semiconductor-compatible fabrication are desired. Conductive oxides may be preferred in certain alternative conductive branches. Noble metals may be used in additional alternative conductive branches, particularly where a selected band or design posture makes such materials appropriate. Oxide, fluoride, and semiconductor dielectric families may likewise be selected according to dielectric loss, fabrication compatibility, and intended operating band. Material-family selection is therefore tied to concrete pairings, target bands, loss posture, and regime realization, rather than presented as an abstract list detached from emitter-performance requirements. Representative permittivity values for candidate conductive and dielectric layers may be obtained from tabulated optical constants, literature data, ellipsometry, reflectometry, or other measured epsilon(omega) sources for the stated material and operating band. In one representative workflow, a doped-Si/SiO2 or SiC/SiO2 pair is selected for an 8-14 um band, the conductive and dielectric permittivities are inserted into the effective-medium equations at f=phi\hat{ }−2, and the pair is retained when the opposite-sign condition is verified over the selected operating band. The disclosure also distinguishes between a general loss budget, a preferred low-loss target, and a material-family-specific loss posture so that practical enhancement discussion remains disciplined.

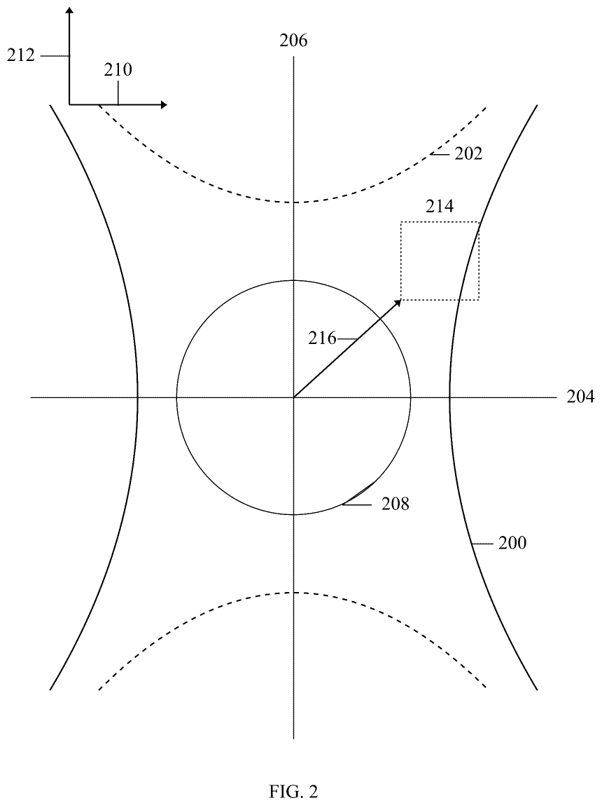

Referring now to FIG. 2, the physical basis for the multilayer hyperbolic response is illustrated through a representative Type I surface 200, a representative Type II surface 202, a k_parallel axis 204, a k_perp axis 206, a conventional dielectric surface 208, an in-plane tensor component 210 corresponding to epsilon_parallel, an out-of-plane tensor component 212 corresponding to epsilon_perp, a high-k mode region 214, and a representative propagation direction 216. The multilayer hyperbolic metamaterial stack 104 may be understood as an effective-medium structure in which the alternating conductive and dielectric layers generate different field responses parallel and perpendicular to the layers. In representative effective-medium treatment, the in-plane permittivity may be expressed as epsilon_parallel=f epsilon_m+(1−f) epsilon_d, while the out-of-plane component may be expressed through 1/epsilon_perp=f/epsilon_m+(1−f)/epsilon_d, where epsilon_m denotes conductive-layer permittivity and epsilon_d denotes dielectric-layer permittivity. Hyperbolic dispersion occurs when epsilon_parallel and epsilon_perp have opposite signs. This opposite-sign tensor condition is the operative criterion for the hyperbolic regime and gives rise to the Type I surface 200 or the Type II surface 202 rather than the conventional dielectric surface 208. The resulting isofrequency behavior supports large-k modes within the high-k mode region 214 and an elevated photonic density of states relative to conventional isotropic media.

The disclosure supports both Type I and Type II hyperbolic operation. In some implementations, the in-plane tensor component 210 is positive while the out-of-plane tensor component 212 is negative, corresponding to the Type I surface 200. In other implementations, the in-plane tensor component 210 is negative while the out-of-plane tensor component 212 is positive, corresponding to the Type II surface 202. These are not merely arbitrary menu options. Rather, they are structured branches arising from the same opposite-sign tensor condition, with regime realization depending on the selected conductive material family, dielectric material family, target operating band, and the maintained phi-scaled fill fraction 314. In the core embodiment, if a candidate material pair does not support the desired opposite-sign tensor structure at f=phi\hat{ }−2 in the target band, the preferred response is to select a different material pair or a different target band rather than alter the core phi-derived stack rule. For a given conductive-layer permittivity epsilon_m(omega) and dielectric-layer permittivity epsilon_d(omega), the effective-medium components are evaluated at the disclosed fill fraction f=phi\hat{ }−2, and the stack is deemed hyperbolic in the selected operating band when, over at least 20 percent fractional bandwidth within that band, Re(epsilon_parallel) and Re(epsilon_perp) have opposite signs. That tie-break discipline is part of the practical design logic preserved by the disclosure.

Because the multilayer hyperbolic metamaterial stack 104 supports large-k states, the photonic density of states of the emitter structure 100 can exceed that of conventional free-space or non-hyperbolic emitters. In representative scaling form, Purcell enhancement may be expressed as F_P=(lambda/2Lambda)\hat{ }2, where Lambda corresponds to the period 310 of the layer stack 300 and lambda is the relevant operating wavelength. By way of non-limiting numerical example, where the operating wavelength lambda is about 10 um and the period 310 is about 97 nm, the resulting Purcell factor is substantially greater than unity, thereby illustrating the architectural reason for selecting a period 310 well below lambda/2 in preferred embodiments. This scaling relation supports the design principle that a smaller period 310 relative to wavelength can increase enhancement, subject to practical limitations including material absorption loss, finite microstructural resolution, and fabrication tolerance. Thus, in preferred implementations, the period 310 is maintained sufficiently below lambda/2 to support useful enhancement while preserving acceptable fabrication and loss posture. The disclosure therefore preserves not only the architectural rule of the stack, but also the practical design posture by which the stack is selected and validated.

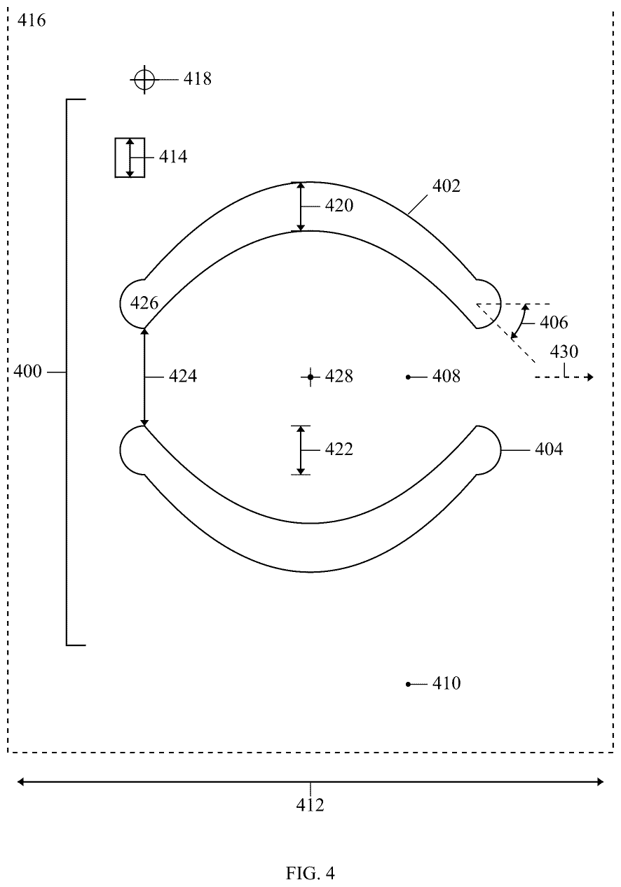

Referring now to FIG. 4, a chi-lattice pattern 400 is formed at the emitting side of the structure and may define a first helical path 402, a second helical path 404, an angular offset 406 corresponding to phi/pi, a first volumetric phase 408, a second volumetric phase 410, a lattice constant 412, a groove depth 414, a pattern cell boundary 416, and a recognition-angle alignment indicator 418. In moderate-detail implementations, the chi-lattice pattern 400 may further define a first path width 420, a second path width 422, an inter-path spacing 424, a local turning node 426, a pattern center 428, and a cell-to-cell repetition direction 430. In representative implementations, the chi-lattice pattern 400 is formed in the top patterned surface 106, such as in a top dielectric layer or top surface region of the multilayer hyperbolic metamaterial stack 104. The chi-lattice pattern 400 is preferably arranged as interpenetrating counter-helical surface features laid out within repeatable pattern cells bounded by the pattern cell boundary 416. In preferred embodiments, the first and second helical paths 402 and 404 are arranged with the angular offset 406 equal to phi/pi, and the relative occupied regions of the first and second volumetric phases 408 and 410 preserve a volumetric ratio phi. These patterned features cooperate with the underlying multilayer emitter so that the resulting structure is not merely a conventional HMM stack with arbitrary surface ornamentation, but rather a combined emitter architecture in which the out-of-plane hyperbolic stack and the in-plane chi-pattern jointly define the thermal-emission behavior of the device.

The chi-lattice pattern 400 may be understood in staged form. At a first level, the emitter structure 100 includes the chi-lattice pattern 400 present at the top patterned surface 106 of the multilayer hyperbolic metamaterial stack 104. At a second level, the chi-lattice pattern 400 includes the first helical path 402 and the second helical path 404 or analogous interpenetrating directional features. At a third level, the first and second helical paths 402 and 404 preserve the angular offset 406 equal to phi/pi in a preferred core-pattern implementation. At a fourth level, the first and second volumetric phases 408 and 410 preserve a volumetric ratio phi in a preferred patterned embodiment. At a fifth level, the chi-lattice pattern 400 supports directional emission behavior. At a sixth level, the chi-lattice pattern 400 supports first-order decoherence cancellation. These staged pattern-side features provide claim-support depth without changing the central technical point that the chi-lattice pattern 400 is part of the operative emitter architecture. As used herein, a chi-lattice surface pattern means an in-plane pattern on an emitting surface that includes at least two interpenetrating elongated features, including grooves, ridges, channels, impedance lines, or equivalent surface features, arranged as oppositely handed spiral, helical, or quasi-helical trajectories within a unit cell. Such oppositely handed trajectories are counter-helical paths. An angular offset of phi/pi means that a mean local tangent direction of a first counter-helical path and a mean local tangent direction of a second counter-helical path differ by phi/pi radians plus or minus 10 percent when averaged over one pattern cell. Directional thermal emission means that, over a stated operating band, an angular power distribution has a primary lobe about a defined surface normal or selected emission axis and satisfies at least one of the following: at least 50 percent of emitted power lies within a cone having a half-angle of 30 degrees about the surface normal or selected emission axis, or a primary-to-largest-sidelobe ratio is at least 6 dB. First-order decoherence cancellation means that, over the stated operating band, a phase-sensitive correlation between paired counter-helical paths has a normalized value of at least 0.7, or that a first-order interference term is suppressed by at least 6 dB relative to an unpatterned control emitter having otherwise identical multilayer composition and thickness. The normalized value is scaled from 0 to 1, with 1 indicating identical phase signatures for paired counter-helical paths under the stated operating band. Measurement protocols, including validated-model requirements and controlled comparison conditions, are described in connection with the design workflow.

The chi-lattice pattern 400 may be implemented through repeatable pattern cells distributed across part or all of the emitting area of the emitter structure 100. Within a given pattern cell bounded by the pattern cell boundary 416, the first and second interpenetrating feature systems may be laid out as paired helical or quasi-helical traces, channels, grooves, ridges, or equivalent surface features whose geometry preserves the intended angular relation and volumetric distribution. In preferred implementations, the chi-lattice pattern 400 is registered to the underlying multilayer hyperbolic metamaterial stack 104 through alignment marks, registration features, lithographic overlay control, or equivalent alignment structures so that the directional outcome of the top patterned surface 106 is preserved relative to the stack geometry and the intended surface normal 118. The groove depth 414, the lattice constant 412, the pattern-cell size defined by the pattern cell boundary 416, and registration accuracy may all affect the eventual directional-emission behavior and should therefore be treated as implementation variables rather than incidental manufacturing details.

The first volumetric phase 408 and the second volumetric phase 410 may be realized geometrically by relative occupied surface regions, groove volumes, phase areas, or analogous interpenetrating pattern portions within the pattern cell bounded by the pattern cell boundary 416. Likewise, the angular offset 406 may be realized through the relative angular disposition of the first helical path 402 and the second helical path 404 or equivalent directional features. In some embodiments, the chi-lattice pattern 400 is periodic. In other embodiments, the chi-lattice pattern 400 is quasi-periodic or locally repeated while still preserving the intended angular and volumetric relations. The disclosure therefore preserves a broad pattern-side architecture while also preserving narrower and more explicit implementations directed to the first and second helical paths 402 and 404, the pattern cell boundary 416, interpenetrating feature layout, the groove depth 414, the lattice constant 412, and registration to the multilayer hyperbolic metamaterial stack 104.

Referring now to FIG. 5, a patterned emitter surface 500 may generate a primary lobe 502, one or more side lobes 504, and a directional cone 508 referenced to a surface normal 506. A first path integral route 510 and a second path integral route 512 may be associated with a cancellation relation indicator 514, and a representative wavefront 516 may be shaped so that a side-lobe suppression indicator 518 reflects reduced off-axis emission relative to the primary lobe 502. The patterned emitter surface 500 corresponds generally to the top patterned surface 106 and to the chi-lattice pattern 400 and illustrates that the in-plane chi-lattice geometry modifies the emission behavior of the multilayer hyperbolic emitter by imparting directional response to the emitted thermal field. In preferred implementations, emission that would otherwise be more weakly directed is concentrated into the primary lobe 502 centered generally about the surface normal 506 or another selected emission axis.

Representative preferred directional anchors include the primary lobe 502 extending within plus or minus 30 degrees of the surface normal 506, concentration of about 70 percent of emitted power into the primary lobe 502 and the associated directional cone 508, and side-lobe suppression greater than 10 dB as reflected by the side-lobe suppression indicator 518 relative to the side lobes 504. These directional values are preserved as preferred support anchors and are not required in every implementation. The broader point is that the patterned emitter surface 500 imparts directional emission behavior and thereby improves coupling into a selected receiver or thermally coupled body, particularly in near-field emitter-receiver assemblies. The directional outcome may also be discussed in relation to a recognition-angle alignment preserved as subordinate support, such as the recognition-angle alignment indicator 418, but that recognition-angle anchor is not required to define the broadest claim family.

The patterned emitter surface 500 also preserves first-order decoherence cancellation in preferred embodiments. In representative form, this behavior may be expressed through the first path integral route 510 and the second path integral route 512, with the cancellation relation indicator 514 representing a paired-path relation in which the integral over a first path of P dot dl, combined with the integral over a second path of P dot dl, sums to zero. This cancellation relation is preserved as operative support for the statement that the chi-lattice pattern 400 preserves first-order decoherence cancellation in preferred patterned embodiments. The disclosure does not require that every claim recite the full integral expression, but the relation remains important support for narrower claims and for explaining why the chi-lattice pattern 400 is not merely a directional grating but a coherence-preserving directional architecture. In this respect, the counter-helical geometry of the first and second helical paths 402 and 404 is not only directional but also phase-structuring. The first path integral route 510 and the second path integral route 512 illustrate that the emitter architecture is intended to shape not merely the angle of emission but also the first-order coherence behavior of the emitted field in preferred implementations.

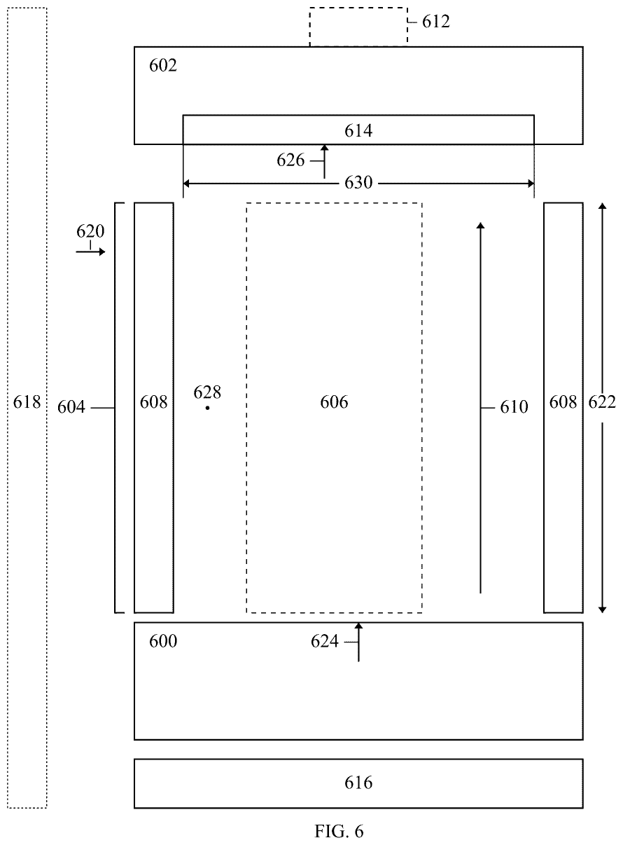

Pattern geometry may be selected in relation to a target wavelength, a desired primary lobe angle, a desired side-lobe suppression level, desired polarization behavior, available fabrication resolution, and acceptable registration tolerance. In representative implementations, the lattice constant 412 is selected to be on the order of the intended operating wavelength, such as within a range of about 5 um to about 15 um for certain preferred mid-infrared builds and in some embodiments near about 10 um for a target wavelength in the mid-infrared atmospheric window. The groove depth 414 may be selected in relation to directional coupling strength, stack integrity, and practical fabrication tolerance, with representative preferred groove depths 414 of about 20 nm to about 50 nm. The angular offset 406 corresponding to phi/pi may be expressed numerically as about 0.515 radians, or about 29.5 degrees, in representative implementations. These dimensions are illustrative and do not limit the broader architecture. The important implementation principle is that the geometry of the first and second helical paths 402 and 404, the registration accuracy of the chi-lattice pattern 400, the lattice constant 412, the groove depth 414, and preservation of the angular offset 406 cooperate to produce the desired directional emitter response. In some implementations, handedness of the first and second helical paths 402 and 404 may also influence polarization behavior. Such handedness-dependent polarization effects are optional refinements and do not redefine the broadest emitter architecture, but they remain expressly supported as narrower implementation detail and dependent-claim territory. Referring now to FIG. 6, an emitter 600 is positioned opposite a receiver 602 across a gap 604. An evanescent coupling region 606 spans the gap 604, and a spacer 608 may maintain the intended emitter-to-receiver separation. A heat-flow direction 610 extends from the emitter 600 toward the receiver 602, and in some implementations an optional contact 612 may couple to a receiver active region 614. The emitter 600 and the receiver 602 may each be supported by a support substrate 616, and an alignment region 618 may help preserve intended registration between the active portions of the assembly. In moderate-detail implementations, FIG. 6 may further include a spacer contact face 620, a gap-control height 622, an emitter-side interface 624, a receiver-side interface 626, a lateral leakage path region 628, and an active overlap width 630 between the emitter 600 and the receiver active region 614. The emitter 600 may correspond to the emitter structure 100, the receiver 602 may correspond to the receiver 110, the gap 604 may correspond to the subwavelength gap 108, and the spacer 608 may correspond to the spacer structure 116. FIG. 6 therefore illustrates the near-field assembly architecture in greater detail and shows that the disclosed emitter is used across a maintained subwavelength spacing from a receiver or other thermally coupled body so that evanescent fields can couple across the gap 604. The support substrate 616 and the alignment region 618 illustrate that the practical assembly is not only an abstract two-body spacing problem but also a packaging and alignment problem in which registration and spacer architecture can materially affect actual performance.

In the assembly of FIG. 6, the relevant near-field condition is that the gap 604 is less than the coupled wavelength lambda. In this regime, thermal transfer between the emitter 600 and the receiver 602 need not be limited to far-field propagating modes. Instead, the evanescent coupling region 606 permits evanescent electromagnetic modes to contribute to inter-surface energy transfer, enabling transfer rates beyond the classical blackbody far-field limit. This near-field operating condition is therefore a core architectural feature of the disclosed use environment and not an incidental deployment detail. In representative scaling form, near-field enhancement may be expressed as F_NF=(lambda/2pi d)\hat{ }2, where d corresponds to the gap 604. Total enhancement may be expressed in representative combined form as F_total=F_P×F_NF×F_directional. By way of non-limiting numerical illustration, where lambda is about 10 um, a gap 604 of about 100 nm yields a much larger near-field factor than a gap 604 of about 500 nm, a gap 604 of about 50 nm yields a still larger factor, and a gap 604 of about 10 nm yields a substantially larger theoretical factor still, subject in each case to practical limits including loss, nonlocal response, roughness, spacer leakage, and fabrication tolerance. These relations are disclosed as support relations, scaling relations, and upper-bound or architecture-explanatory relations, not as guaranteed measured outputs for every implementation. Rather, they show that the disclosed architecture can produce enhancement through three cooperating mechanisms: elevated photonic density of states associated with the multilayer hyperbolic metamaterial stack 104, subwavelength-gap coupling associated with the gap 604 and the evanescent coupling region 606, and directional concentration associated with the chi-lattice pattern 400 and the patterned emitter surface 500.

Practical performance of the assembly of FIG. 6 depends on additional constraints. These include conductive and dielectric loss in the emitter 600, nonlocal response at small feature scales or small values of the gap 604, finite gap-control accuracy by the spacer 608, surface roughness, parasitic conduction through spacers or surrounding assemblies, and lateral heat spreading through the support substrate 616 or neighboring materials. Because of these practical constraints, the disclosure distinguishes between analytical or modeled scaling support, preferred practical enhancement ranges, and application-level output statements. A scaling relation may establish that enhancement should increase as the gap 604 is reduced or as the multilayer period is reduced, while a practical design may deliver a smaller but still useful enhancement because of loss and fabrication posture. By way of example, a modeled embodiment using a mid-infrared operating band, a period 310 of about 97 nm, and a gap 604 of about 100 nm may provide a practical enhancement posture materially above a far-field baseline, while a smaller gap 604 such as about 50 nm may provide a still larger modeled transfer posture if loss and fabrication limits remain acceptable. Such modeled examples are provided as architecture-supporting numerical illustrations and not as measured prototype data. This support-tier distinction is maintained throughout the present disclosure to avoid conflating theoretical, modeled, practical, and prophetic statements. It also means that output values associated with later TPV, cooling, switching, or sensing embodiments should not be read back into the core emitter architecture as if they were all measured hardware results.

Gap architecture may also be described in staged form. At a first level, the emitter 600 is used across a subwavelength gap 604. At a second level, the gap 604 is maintained by the spacer 608. At a third level, the gap 604 is maintained within a preferred numeric range, such as about 10 nm to about 500 nm in representative implementations. At a fourth level, the gap 604 may be fixed. At a fifth level, the gap 604 may be variable. Preferred practical builds may use values of the gap 604 in the 50 nm to 100 nm range where useful enhancement can be achieved while preserving manufacturability and spacer reliability. Surface roughness is preferably maintained below about d/10 so that the intended near-field spacing is not effectively destroyed by asperity contact or excessive local gap variation. The disclosure therefore preserves not only the presence of a near-field gap but also a spacer-maintained gap architecture, a preferred numeric gap range, and fixed-gap and variable-gap branches as separate fallback positions.

The disclosed system architecture may therefore include the emitter 600, the gap 604, one or more spacers 608, the receiver 602 or other thermally coupled body, one or more support substrates 616, and optionally a package or housing. The receiver 602 may be any body capable of receiving thermal radiation coupled from the emitter 600 across the gap 604. In a broad receiver-side ladder, the counterpart structure may be a generic receiver 602. In narrower embodiments, the receiver 602 may be a photovoltaic receiver. In still narrower embodiments, the receiver 602 may be a rectifying receiver. Particular examples include HgCdTe photovoltaic receivers and chi-grid rectenna receivers, both of which are preserved as receiver-specific embodiments without defining the invention by either one. The optional contact 612 and the receiver active region 614 illustrate that the receiver side may, but need not, include electrical-conversion structures. In broader non-electrical branches, the counterpart across the gap 604 may instead be a thermally coupled body, a cooling surface, a switchable thermal counterpart, or a sensor-side detector body.

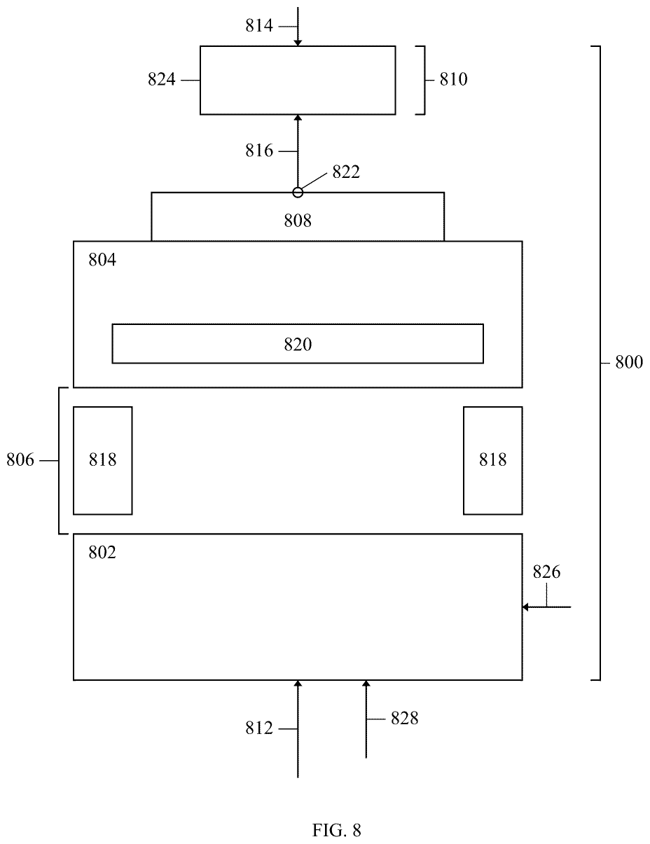

Referring now to FIG. 8, an electrical-conversion system 800 includes an emitter 802 positioned opposite a receiver 804 across a gap 806. One or more electrical contacts 808 may couple to the receiver 804, and a load or storage element 810 may receive electrical output from the receiver 804. A hot side 812 and a cold side 814 define a thermal gradient across the system 800, and an output-current path 816 may extend from the receiver 804 toward the load or storage element 810. A spacer 818 may maintain the gap 806. In moderate-detail implementations, FIG. 8 may further include a receiver junction or rectifying region 820, a collection node 822, an external circuit connection 824, a thermal input sidewall or boundary 826, and a thermal sink coupling region 828. The emitter 802 may correspond generally to the emitter structure 100 or emitter 600, the receiver 804 may correspond generally to the receiver 110 or receiver 602, and the spacer 818 may correspond generally to the spacer structure 116 or spacer 608. FIG. 8 therefore illustrates a preferred electrical-conversion branch in which the disclosed emitter architecture is paired with a receiver for thermal-to-electrical conversion. The hot side 812 and the cold side 814 also show that the system can be understood as an emitter-receiver architecture operating across a thermal differential rather than only as a static structural arrangement.

In the electrical-conversion system 800, the receiver 804 may be configured as a photovoltaic receiver, detector-like semiconductor receiver, rectifying receiver, rectenna, or analogous structure selected for the relevant operating band. In a photovoltaic branch, the receiver 804 may include a semiconductor junction, absorber, detector, or analogous photoresponsive structure selected for the relevant thermal radiation band. In a rectifying branch, the receiver 804 may include a rectifying antenna, a chi-grid rectenna, a nonlinear receiving element, or another receiver-side extraction structure. The electrical contacts 808, the load or storage element 810, and the output-current path 816 illustrate that receiver-side conversion and collection circuitry may be coupled to the receiver 804 in these preferred and downstream implementations. By way of non-limiting modeled example, where the emitter 802 operates near body temperature or another relatively low-delta-T condition and the gap 806 is maintained at a nanoscale spacing, the system 800 may provide a modeled thermal-to-electrical conversion posture above a far-field counterpart, and where the hot side 812 is raised further above the cold side 814 the same architecture may provide a larger modeled conversion posture. These application-level output discussions remain illustrative, modeled, target-based, or prophetic unless measurement support is separately provided.

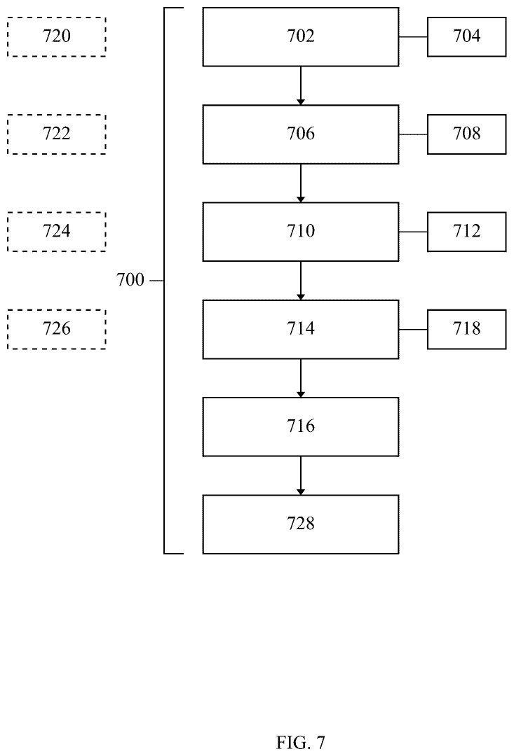

Referring now to FIG. 7, a fabrication workflow 700 may include a deposition stage 702 performed with a multilayer deposition tool 704, a patterning stage 706 involving lithographic pattern transfer 708, a spacer formation stage 710 producing a spacer element 712, and a bonding stage 714 resulting in an assembled device 716. One or more registration features 718 may be used during this workflow to maintain pattern-to-stack registration and emitter-to-receiver registration. In moderate-detail implementations, FIG. 7 may further include a thickness-control step 720, an etch-depth control step 722, an overlay verification step 724, a gap-verification step 726, and a final acceptance output 728. The deposition stage 702 may be used to form the multilayer hyperbolic metamaterial stack 104 or the layer stack 300 with the intended ratio between the metal thickness 308 and the dielectric thickness 306. The patterning stage 706 may be used to form the chi-lattice pattern 400 in the top patterned surface 106. The spacer formation stage 710 may be used to define the spacer structure 116, the spacer 608, or the spacer 818. The bonding stage 714 may be used to assemble the emitter with the receiver across the intended subwavelength gap. FIG. 7 therefore illustrates make-and-use support for the disclosed emitter architecture and shows that the invention is not merely a conceptual geometry but a fabricable multilayer-and-pattern assembly.

The multilayer deposition tool 704 may represent physical vapor deposition, sputtering, evaporation, chemical vapor deposition, plasma-enhanced chemical vapor deposition, atomic layer deposition, pulsed deposition, or another suitable thin-film process for building the multilayer hyperbolic metamaterial stack 104 or the layer stack 300. The lithographic pattern transfer 708 may represent electron-beam lithography, optical lithography, nano-imprint lithography, direct-write patterning, etch-defined transfer, lift-off-defined feature formation, embossing, or another structure-preserving method for forming the chi-lattice pattern 400. The spacer element 712 may be a discrete spacer, a perimeter spacer, a pillar spacer, a MEMS spacer, or an actuated spacer architecture. The assembled device 716 may be a standalone emitter package, an emitter-receiver assembly, or another integrated structure preserving the active near-field region. The particular fabrication tools are not themselves the invention, but they are preserved as enablement support because practical realization depends on maintaining the 1/phi layer ratio, the phi\hat{ }−2 fill fraction, the pattern geometry, the registration posture, and the intended gap architecture.

Registration is an important implementation variable and is treated distinctly from general fabrication tolerance. The registration feature 718 may be used to support pattern-to-stack registration affecting whether the chi-lattice pattern 400 is positioned as intended relative to the multilayer hyperbolic metamaterial stack 104 and the intended surface normal 118. The registration feature 718 may also support emitter-to-receiver registration affecting whether the active near-field region, patterned directional response, and receiver-side active region are aligned as intended in the assembled device 716. Registration therefore affects directional outcome, coupling behavior, and assembled device performance. The disclosure distinguishes between general thickness or feature-size tolerance on the one hand, and registration-specific tolerance on the other hand, so that later claim drafting and enablement support can treat those as separate implementation topics rather than as a single undifferentiated manufacturing issue. In some builds, registration tolerance may primarily affect preservation of the primary lobe 502 and suppression of the side lobes 504. In other builds, registration tolerance may primarily affect how well the thermal flux path 112 or the heat-flow direction 610 couples into the receiver active region 614 or other selected counterpart structure. Thus, registration is preserved as a distinct part of the make-and-use architecture of the disclosed emitter system.

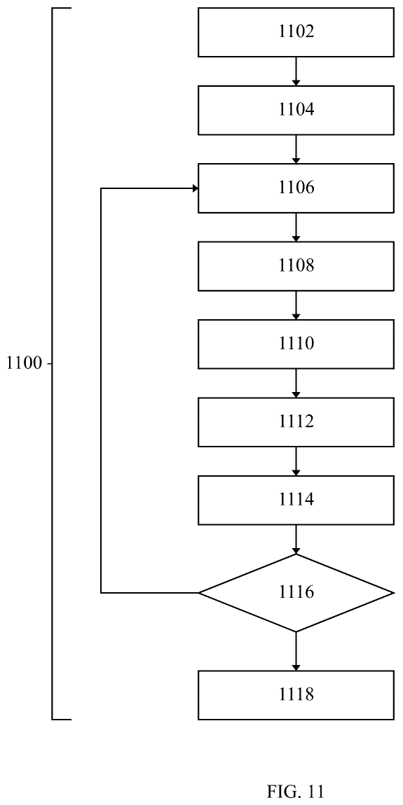

Referring now to FIG. 11, a design workflow 1100 may begin with a target-band input 1102, followed by a material-selection module 1104, an effective-medium calculation 1106, a stack-rule application 1108, a pattern-selection module 1110, an enhancement calculation 1112, a fabrication-tolerance check 1114, a formal-verification branch 1116, and a validated design output 1118. The design workflow 1100 provides a representative path for selecting, validating, and refining implementations of the disclosed emitter architecture. In one approach, the target-band input 1102 identifies a desired operating wavelength band, such as a mid-infrared band or another selected thermal-emission band. The material-selection module 1104 then selects candidate conductive and dielectric material pairs suitable for that band and for the intended fabrication posture. The stack-rule application 1108 imposes the phi-derived stack rule by setting d_m/d_d=1/phi and thereby deriving f=phi\hat{ }−2. The effective-medium calculation 1106 then evaluates whether the selected material pair, combined with the imposed fill fraction, yields opposite-sign tensor components in the intended band. If the selected pair does not support the desired sign structure at the phi-derived fill fraction in the intended band, the preferred design response is to change the material pair or target band rather than alter the core phi-derived stack rule in the core embodiment. In this way, the design workflow 1100 preserves the determinative role of the stack rule while still allowing materials and band selection to vary.

After the stack posture is determined, the pattern-selection module 1110 may be used to select the geometry of the chi-lattice pattern 400, including the first helical path 402, the second helical path 404, the angular offset 406, the first and second volumetric phases 408 and 410, the lattice constant 412, and the groove depth 414. The enhancement calculation 1112 may then estimate Purcell enhancement, near-field enhancement, directional concentration, and a representative total enhancement posture. The fabrication-tolerance check 1114 may evaluate whether the selected stack dimensions, feature depths, registration posture, spacer posture, roughness limits, and thermal budget are compatible with practical fabrication. In some implementations, the formal-verification branch 1116 may also be used before release of the validated design output 1118 so that selected exact relations or model predicates are checked using analytical, model-based, or formalized support. In this way, the design workflow 1100 supports both technical design selection and prosecution-support discipline. It also provides a concrete make-and-use path that connects the architectural rules of the specification to an actual selection and validation sequence a practitioner can follow.

Tie-break rules may be used within the design workflow 1100. If multiple material pairs satisfy the opposite-sign tensor condition, the material-selection module 1104 may prefer the pair having lower loss in the target band or a better fabrication posture for the intended support tier. If multiple lattice constants are viable, the pattern-selection module 1110 may prefer a lattice constant 412 nearer the intended operating wavelength while preserving feature fidelity and practical manufacturability. If multiple groove depths are viable, the pattern-selection module 1110 may select the groove depth 414 that maintains directional response and fabrication reliability without materially degrading the multilayer hyperbolic metamaterial stack 104. If a candidate design cannot preserve the phi-derived layer relation and still fabricate reliably, that candidate may be treated as an optional or alternative build rather than as a basis for altering the core structural rule. Acceptance criteria at the design-support level may include satisfaction of the fill-fraction identity, achievement of a hyperbolic regime in the selected operating band, achievement of a subwavelength-gap posture, support for directional emission, predicted enhancement exceeding a selected baseline, acceptable fabrication and integration posture, and support-tier labeling appropriate to any stated performance value. For this purpose, super-Planckian near-field radiative transfer means radiative heat transfer between an emitter and a receiver across a gap d that exceeds a far-field blackbody transfer rate computed for the same temperatures and projected area by at least 2 times over the stated operating band, as determined by calorimetry or by a validated fluctuational-electrodynamics model using stated material permittivities. In preferred embodiments, the chi-lattice pattern is evaluated against an unpatterned control emitter having the same multilayer composition, layer thicknesses, active area, and operating band, and the patterned emitter provides at least one of a 6 dB improvement in primary-to-largest-sidelobe ratio or a 2 times increase in coupled transfer to a matched receiver at the same gap relative to the unpatterned control. Accordingly, the workflow 1100 is not only a design path but also a discipline for preserving consistency between the architecture, the support record, and any eventual claim language. Measurement protocols may be applied consistently across the disclosed metrics. The angular power distribution P(theta) may be determined by far-field measurement at a distance of at least 10 times the lateral unit-cell pitch, by near-field scanning within 2 times the pitch, or by a validated electromagnetic model using stated material permittivities and stated boundary conditions. The far-field blackbody comparator is computed for the same temperatures, projected area, and stated operating band as the tested emitter-receiver configuration. A validated model means a fluctuational-electrodynamics, effective-medium, finite-element, finite-difference time-domain, rigorous coupled-wave, or equivalent model whose material permittivities, gap dimension, geometry, and boundary conditions are stated sufficiently to reproduce the calculated comparison. Unless otherwise stated, comparative tests hold emitter temperature, receiver temperature, projected active area, gap, material pair, multilayer thickness, and operating band constant between the patterned emitter and the comparison emitter.

The disclosure further preserves formalized and machine-verified support for selected exact relations and inequalities. Within the design workflow 1100, the formal-verification branch 1116 may preserve or invoke support corresponding to fill_fraction_eq, purcell_enhanced establishing that Purcell enhancement exceeds unity when Lambda is less than lambda/2, near_field_super_planckian establishing that near-field enhancement exceeds unity when d is less than lambda divided by 2pi, total_exceeds_components, chi_volume_ratio, coherence_exponent_eq_5, and sum_8_phases_eq_zero. The formal-verification branch 1116 may also preserve master-certificate type support linking coherence exponent equal to 5 and eight-tick phase cancellation. This formal material supports internal coherence, exact derived relations, and claim-support architecture. It does not, by itself, constitute hardware prototype validation, measured directional-emission data, measured switching data, or measured device-output data. That distinction is preserved expressly so that formal support is used in the proper lane and so that analytical, modeled, practical, and prophetic support tiers do not become blurred in prosecution or later continuation practice.

The disclosure also preserves several embodiment families arranged in a deliberate hierarchy. A first embodiment family is the standalone emitter device, such as the emitter structure 100, the multilayer hyperbolic metamaterial stack 104, the top patterned surface 106, the layer stack 300, and the chi-lattice pattern 400, configured for directed thermal emission without requiring that a receiver, maintained operating gap, or electrical-extraction feature be recited in the embodiment-defining sentence. A second embodiment family is the emitter-receiver or emitter-body assembly, such as the emitter 600 and the receiver 602 across the gap 604 maintained by the spacer 608. A third embodiment family includes preferred electrical-conversion branches, such as the electrical-conversion system 800. A fourth embodiment family includes downstream non-electrical branches, such as the cooling system 900, the thermal switch 1000, and the sensor system 1200. This hierarchy is preserved so that downstream branches do not overshadow the core emitter architecture and so that broad device-root and method-root claim families remain well supported even if a particular downstream market branch later changes or is pursued in a separate continuation.

Referring now to FIG. 9, a cooling system 900 may include an emitter surface 902 arranged to emit along an upward emission path 904 toward a sky-facing direction 906 while suppressing a suppressed downward path 908. A reflective backing 910 may be provided behind or below the active emitter structure, and a cooled object or substrate 912 may be thermally coupled to the system 900. The cooling behavior may be associated with an atmospheric window band 914 and a directional cone 916. The cooling system 900 is a secondary downstream embodiment illustrating that the disclosed emitter architecture can be used to direct thermal radiation preferentially toward a cooling direction while suppressing undesired lateral or downward exchange. In such embodiments, the emitter surface 902 may correspond to the top patterned surface 106 or the patterned emitter surface 500, and the directional cone 916 may correspond generally to the directional cone 508. By way of non-limiting modeled example, where the emitter surface 902 is operated near ambient temperature and the directional cone 916 is aligned with the atmospheric window band 914, the cooling system 900 may provide a modeled net radiative-cooling posture greater than a less directional counterpart while the reflective backing 910 reduces undesired exchange into non-sky-facing directions. The cooling system 900 is preserved as a downstream application branch and does not redefine the core emitter architecture. Any numerical cooling-power values associated with the cooling system 900 remain modeled, target-based, or prophetic unless corresponding measurements are later provided.

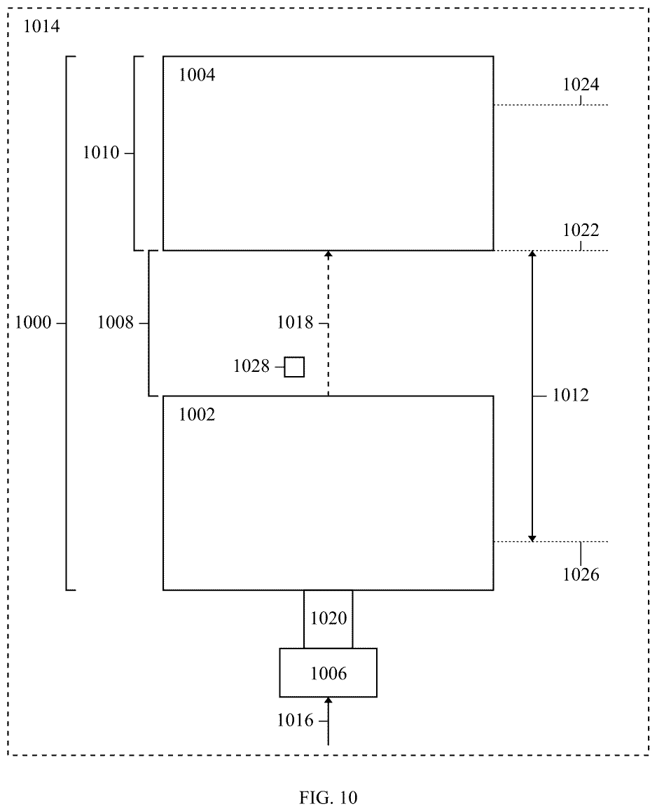

Referring now to FIG. 10, a thermal switch 1000 may include an emitter 1002, a receiver 1004 or other thermal counterpart, an actuator 1006, an ON-state gap 1008, an OFF-state gap 1010, a movement direction 1012, a support frame 1014, a control input 1016, and a thermal-flow path 1018. In moderate-detail implementations, FIG. 10 may further include an actuator linkage 1020, a travel limit 1022, an ON-state position 1024, an OFF-state position 1026, and an alignment stop 1028. The actuator 1006 may vary the spacing between the emitter 1002 and the receiver 1004 along the movement direction 1012 so that the ON-state gap 1008 supports stronger near-field coupling while the OFF-state gap 1010 supports reduced coupling. The support frame 1014 may maintain overall assembly alignment, and the control input 1016 may provide electrical, thermal, piezoelectric, electrostatic, magnetic, or other actuation control. By way of non-limiting modeled example, the ON-state gap 1008 may be selected within a preferred nanoscale near-field range while the OFF-state gap 1010 is selected at a larger spacing that materially reduces evanescent coupling, such that the thermal-flow path 1018 is greater in an ON state than in an OFF state. The thermal switch 1000 is a secondary downstream embodiment showing that the disclosed emitter architecture may be incorporated into a variable-gap thermal-switch system. However, any switching-ratio values associated with such a system remain illustrative, modeled, or prophetic unless measured support is later added, and the switching function does not define the invention at its core. The switch embodiment therefore remains subordinate to the emitter architecture and is not intended to pull the disclosure away from its device-centered foundation.

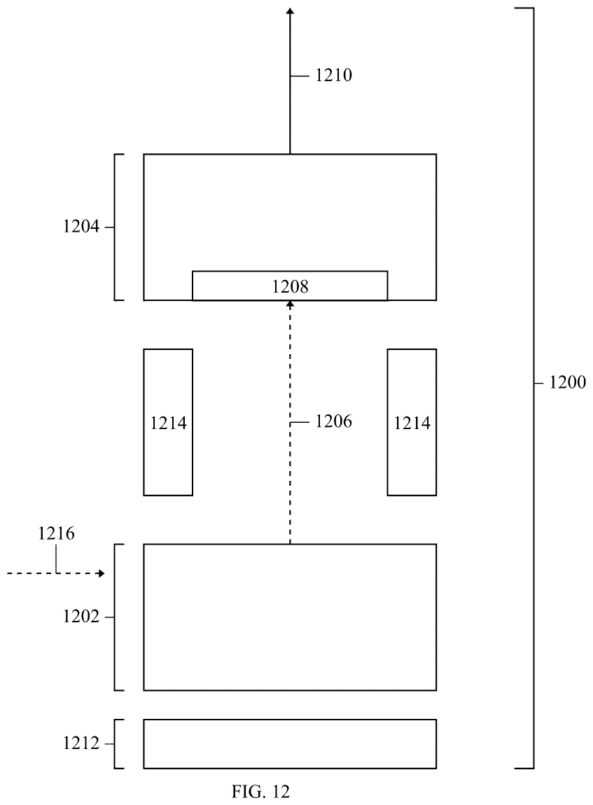

Referring now to FIG. 12, a sensor system 1200 may include an emitter 1202, a detector 1204, a near-field concentration region 1206, a detector active area 1208, a signal output 1210, a support substrate 1212, an alignment spacer 1214, and an incident thermal field 1216. In this secondary downstream embodiment, the emitter 1202 may direct or concentrate thermally emitted or coupled radiation into the detector active area 1208 through the near-field concentration region 1206 so that effective detector response is increased relative to a non-concentrating configuration. The alignment spacer 1214 may preserve spacing and registration between the emitter 1202 and the detector 1204, and the signal output 1210 may represent any electrical, optical, thermal, or mixed-domain output associated with the detector 1204. The sensor system 1200 is preserved as a downstream sensing embodiment. Any detector-gain or sensitivity values associated with the sensor system 1200 remain illustrative, modeled, or prophetic unless corresponding measurements are later introduced. The sensing embodiment thus preserves application depth without converting modeled architecture support into an implied hardware reduction to practice.

The disclosure also preserves alternative embodiments and fallback positions across multiple technical axes. On the stack side, support is preserved for an alternating metal-dielectric multilayer stack, a fixed 1/phi layer ratio, a resulting phi\hat{ }−2 fill fraction, a stack in which phi\hat{ }−2 is structurally motivated, a stack in which phi\hat{ }−2 supports bandwidth posture, a stack in which phi\hat{ }−2 supports tolerance posture, and a stack in which phi\hat{ }−2 supports loss-balancing posture. On the pattern side, support is preserved for a surface pattern generally, counter-helical paths such as the first and second helical paths 402 and 404, an angular offset such as the angular offset 406, a volumetric ratio implemented through the first and second volumetric phases 408 and 410, directional-emission support such as the primary lobe 502 and the directional cone 508, and first-order decoherence-cancellation support such as the first and second path integral routes 510 and 512 together with the cancellation relation indicator 514. On the implementation side, support is preserved for a pattern cell defined by the pattern cell boundary 416, interpenetrating feature layout, registration to the multilayer hyperbolic metamaterial stack 104, groove depth selection such as the groove depth 414, and lattice-constant selection such as the lattice constant 412. These fallback positions are embedded in the narrative so that they function as real written-description support rather than as after-the-fact claim labels.

On the gap side, support is preserved for a subwavelength gap such as the subwavelength gap 108, the gap 604, or the gap 806, a spacer-maintained gap such as by the spacer structure 116, the spacer 608, or the spacer 818, a gap within preferred numeric ranges, a fixed gap, and a variable gap. On the receiver side, support is preserved for a generic receiver such as the receiver 110, the receiver 602, or the receiver 804, a photovoltaic receiver, a rectifying receiver, an HgCdTe receiver, and a chi-grid rectenna receiver. On the directional-performance side, support is preserved for directional emission generally, a primary lobe centered about a surface normal such as the primary lobe 502 about the surface normal 506, a plus or minus 30 degree cone such as the directional cone 508 or 916, concentration of about 70 percent of emitted power, and side-lobe suppression greater than 10 dB such as reflected by the side-lobe suppression indicator 518. On the fabrication side, support is preserved for multilayer deposition through the deposition stage 702 and the multilayer deposition tool 704, surface-pattern registration through the registration feature 718, spacer-controlled gap through the spacer element 712, roughness below a preferred threshold, and temperature-budget-limited fabrication. On the formal-support side, support is preserved for design calculation, analytical confirmation, formal or model verification, specific proof-hook verification, and master-certificate verification such as through the formal-verification branch 1116.

The foregoing fallback positions are presented with primary emphasis on stack, pattern, gap, directional performance, fabrication tolerance, registration, spacer architecture, and formal-support structure, while materials-family grounding, operating-band grounding, regime-selection grounding, and loss-budget grounding remain subordinate narrowing aids. Application-level outputs and downstream use branches likewise remain subordinate to the core emitter architecture.

The disclosed written description supports broad method, device, and system claim families directed to the phi-scaled, chi-structured emitter, use across a subwavelength gap, evanescent coupling, and corresponding receiver or thermally coupled body implementations, with narrower support preserved through the staged stack-side, pattern-side, pattern-geometry, gap-side, receiver-side, directional-performance, fabrication-tolerance, fabrication-registration, spacer-architecture, and formal-verification fallback positions described above. The disclosure also preserves secondary architecture anchors for narrower claim families and possible continuation practice, including extraction locked to integer multiples of E_coh=phi\hat{ }−5, synchronization to an eight-tick cadence, recognition-angle alignment such as by the recognition-angle alignment indicator 418, and master-certificate support linking coherence exponent equal to 5 and eight-tick phase cancellation.

From the foregoing, it will be appreciated that the disclosed subject matter provides a coherent emitter-centered architecture in which the multilayer hyperbolic metamaterial stack 104 and the chi-lattice surface pattern 400 are jointly structured, the stack is fixed by a phi-derived layer rule yielding the fill fraction 314 equal to phi\hat{ }−2, the patterned emitter surface 500 imparts directional emission and preserves first-order decoherence cancellation in preferred embodiments, and the emitter structure 100 is configured for use across the subwavelength gap 108 to support super-Planckian near-field radiative transfer. Variations may be made in materials, dimensions, fabrication methods, receiver type, gap-control architecture, application branch, and support tier without departing from the scope of the disclosed invention.

What is claimed is:

1. A near-field thermal emitter device comprising: a substrate; a multilayer hyperbolic metamaterial stack supported by the substrate and comprising alternating conductive layers and dielectric layers, wherein the multilayer hyperbolic metamaterial stack has a conductive-to-dielectric thickness ratio of 1/phi, thereby yielding a conductive fill fraction of phi\hat{ }−2; and a chi-lattice surface pattern at an emitting side of the multilayer hyperbolic metamaterial stack, the chi-lattice surface pattern including counter-helical paths arranged so that, over a selected operating band, at least 50 percent of emitted power lies within a cone having a half-angle of 30 degrees about a surface normal or a primary-to-largest-sidelobe ratio is at least 6 dB, wherein the multilayer hyperbolic metamaterial stack is configured to satisfy an opposite-sign condition between epsilon_parallel and epsilon_perp over the selected operating band at f=phi\hat{ }−2.

2. The device of claim 1, wherein the chi-lattice surface pattern includes an angular offset of phi/pi between interpenetrating counter-helical paths.

3. The device of claim 1, wherein the chi-lattice surface pattern includes interpenetrating pattern phases arranged in a volumetric ratio of phi.

4. The device of claim 1, wherein the chi-lattice surface pattern is configured to preserve first-order decoherence cancellation by providing a phase-sensitive correlation between paired counter-helical paths having a normalized value of at least 0.7 or by suppressing a first-order interference term by at least 6 dB relative to an unpatterned control emitter having otherwise identical multilayer composition and thickness.

5. The device of claim 1, wherein the opposite-sign condition is satisfied over at least 20 percent fractional bandwidth within the selected operating band.

6. The device of claim 1, wherein the conductive layers comprise a doped silicon material, a phonon-polaritonic silicon carbide material, a conductive oxide material, or a noble metal material.

7. The device of claim 1, wherein the dielectric layers comprise an oxide dielectric, a fluoride dielectric, or a semiconductor dielectric.

8. The device of claim 1, wherein the multilayer hyperbolic metamaterial stack has a period sufficiently smaller than a wavelength in the selected operating band to provide Purcell enhancement.

9. The device of claim 1, wherein the device is configured for operation in a mid-infrared band.

10. The device of claim 9, wherein the mid-infrared band includes an 8-14 um band.

11. A near-field thermal transfer system comprising: an emitter comprising: a multilayer hyperbolic metamaterial stack comprising alternating conductive layers and dielectric layers, wherein the multilayer hyperbolic metamaterial stack has a conductive-to-dielectric thickness ratio of 1/phi, thereby yielding a conductive fill fraction of phi\hat{ }−2; and a chi-lattice surface pattern at an emitting side of the multilayer hyperbolic metamaterial stack, the chi-lattice surface pattern including counter-helical paths arranged so that, over a selected operating band, at least 50 percent of emitted power lies within a cone having a half-angle of 30 degrees about a surface normal or a primary-to-largest-sidelobe ratio is at least 6 dB, wherein the multilayer hyperbolic metamaterial stack is configured to satisfy an opposite-sign condition between epsilon_parallel and epsilon_perp over the selected operating band at f=phi\hat{ }−2; a receiver positioned opposite the emitter across a subwavelength gap; and at least one spacer maintaining the subwavelength gap between the emitter and the receiver, wherein the emitter is configured to couple evanescent electromagnetic modes across the subwavelength gap to produce radiative heat transfer exceeding a far-field blackbody transfer rate computed for the same temperatures, projected area, and selected operating band by at least 2 times.

12. The system of claim 11, wherein the subwavelength gap is between 10 nm and 500 nm.

13. The system of claim 11, wherein the at least one spacer comprises a discrete spacer, a perimeter spacer, a pillar spacer, a MEMS spacer, or an actuated spacer.

14. The system of claim 11, wherein the receiver is a photovoltaic receiver.

15. The system of claim 11, wherein the receiver is a rectifying receiver.

16. The system of claim 11, wherein the receiver comprises an HgCdTe receiver or a chi-grid rectenna receiver.

17. The system of claim 11, wherein the chi-lattice surface pattern is configured to direct thermal emission into a primary lobe centered about a surface normal of the emitter.

18. The system of claim 17, wherein the primary lobe extends within plus or minus 30 degrees of the surface normal.

19. The system of claim 17, wherein the chi-lattice surface pattern provides at least a 6 dB improvement in a primary-to-largest-sidelobe ratio relative to an unpatterned control emitter having identical multilayer composition, layer thicknesses, active area, and operating band.

20. A method of near-field thermal transfer comprising: providing an emitter comprising a multilayer hyperbolic metamaterial stack having alternating conductive and dielectric layers arranged at a conductive-to-dielectric thickness ratio of 1/phi, thereby yielding a conductive fill fraction of phi\hat{ }−2, and further having a chi-lattice surface pattern at an emitting side of the multilayer hyperbolic metamaterial stack; positioning the emitter across a subwavelength gap from a receiver or other thermally coupled body; and coupling evanescent electromagnetic modes across the subwavelength gap to transfer thermal energy at a rate exceeding a far-field blackbody transfer rate computed for the same temperatures and projected area.
